(19) United States
(12) Patent Application Publication
(10) Pub. No.: US 2013/0273363 A1
(43) Pub. Date: Oct. 17, 2013

(54) Freestanding Network of Carbon Nanofibers

(71) Applicants: Eyassu Woldensenbet, Baton Rouge, LA (US); Ephraim Zegeye, Baton Rouge, LA (US); Yoonyoung Jin, Baton Rouge, LA (US)

(72) Inventors: Eyassu Woldensenbet, Baton Rouge, LA (US); Ephraim Zegeye, Baton Rouge, LA (US); Yoonyoung Jin, Baton Rouge, LA (US)

(21) Appl. No.: 13/445,127

(22) Filed: Apr. 12, 2012

(51) Int. Cl. C23C 16/46; B32B 9/00; B82Y 40/00

(52) U.S. Cl. 428/367; 264/81; 977/891

(57) ABSTRACT

The present invention relates to a freestanding network of carbon nanofibers. The present invention further relates to a method of fabricating a freestanding network of carbon nanofibers. Carbon nanofibers are synthesized glass microballoons that are self-assembled on a silicon wafer.

### CROSS-REFERENCE TO RELATED APPLICATIONS

Not applicable

### FEDERALLY SPONSORED RESEARCH

Not applicable

### SEQUENCE LISTING OR PROGRAM

Not applicable

### FIELD OF INVENTION

The present invention relates to a freestanding network of carbon nanofibers. Also disclosed is a method of fabricating a freestanding network of carbon nanofibers.

### BACKGROUND OF INVENTION

Carbon nanotubes and carbon nanofibers are generally well known in the prior art. Carbon nanotubes are allotropes of carbon with a cylindrical nanostructure. Carbon nanofibers are cylindrical nanostructures with graphene layers that may be arranged as either stacked cones, stacked cups, or stacked plates. Due to their unusual strength, flexibility, and electrochemical properties, carbon nanotubes (CNTs) and carbon nanofibers (CNFs) are currently being studied for implementation in a variety of applications. CNTs and CNFs are being utilized for such purposes as electronics, microelectronics, optics, materials science, chemical sensing, biosensing, and nanotechnology. CNFs have been suggested for use as catalytic films in dye-sensitized solar cells and fuel cells, biomimetic adhesives, flexible heaters, super-capacitor electrodes, cell-based biosensors, and thin film conductive composites, while CNTs have been used as fillers in a polymer-matrix to enhance their mechanical, electrical, and thermal properties. Although large scale structures such as composites are considered to benefit from carbon nano-scale materials in order to achieve better mechanical, thermal, and electrical properties, the prior art recognizes a number of deficiencies related to the use of such nano-scale materials. Issues such as dispersion, interfacial, strength, and alignment are recognized deficiencies. With respect to dispersion, the uniform dispersion of CNFs in the polymer matrix phase is an essential prerequisite to achieving consistency in properties of polymer nanocomposites in fields such as microelectronics, aerospace, biology and energy. Due to the lack of uniformity inherent in the common growth methods of CNFs, CNTs are not grown in such a manner as to sufficiently contact with adjacent CNTs to sufficiently facilitate useful levels of conductivity.

The present invention addresses the prior art shortcomings, by presenting a novel freestanding network of carbon nanofibers with improved dispersity, interfacial strength, and alignment, as well as a method of fabricating the same.

### BRIEF SUMMARY OF THE INVENTION

The present, invention relates to a freestanding network of carbon nanofibers. The present invention further relates to a method of fabricating a freestanding network of carbon nanofibers. In one aspect of the invention, a freestanding paper form of CNFs is fabricated by growing the CNFs on the surface of micro-sized low density glass microballoons (GMBs). The synthesis of CNFs is accomplished via a method of water assisted chemical vapor deposition (CVD). As the length of CNFs increase, the CNFs connect the GMBs radially and vertically forming an interlinking network. This interlinking network results in a free standing paper of CNFs and GMBs. The freestanding paper (GMB-CNF paper) has advantages in a variety applications, such as but not limited to, use as an electrode material for super capacitors and Li-ion batteries, as well as enhancing phase material in polymer nanocomposites and other similar applications.

Indeed other advantages, novel features, and applications of the GMB-CNF paper will become more apparent from the following detailed description of preferred embodiments when taken in conjunction with the accompanying drawings.

### BRIEF DESCRIPTION OF DRAWINGS

FIG. 1 is a schematic sectional view showing the GMB-CNF paper according to the present invention.

FIG. 2a represents the EDX spectra of Ni coated microballoons.

FIG. 2b represents the SEM image of a Ni coated microballoons.

FIG. 2c represents the typical optical micrograph of a layer of Ni coated microballoons formed on a Si wafer.

FIG. 3a is the SEM image of GMB-CNF piece for 5 minutes of growth.

FIG. 3b is the SEM image of GMB-CNF piece for 10 minutes of growth.

FIG. 3c is the SEM image of GMB-CNF piece for 20 minutes of growth.

FIG. 3d is a magnified SEM image of GMB-CNF piece for 5 minutes of growth.

FIG. 3e is a magnified SEM image of GMB-CNF piece for 10 minutes of growth.

FIG. 3f is a magnified SEM image of GMB-CNF piece for 20 minutes of growth.

FIG. 4a shows the peeling of the GMB-CNF paper.

FIG. 4b shows the peeled off GMB-CNF paper lifted with forceps.

FIG. 4c represents the SEM image of the GMB-CNF paper.

FIG. 5a shows the TEM image of the CNFs with higher magnification insert.

FIG. 5b shows the Raman spectroscopy of the CNFs.

FIG. 6 shows the average J-E characteristics of the GMB-CNF paper samples at room temperature.

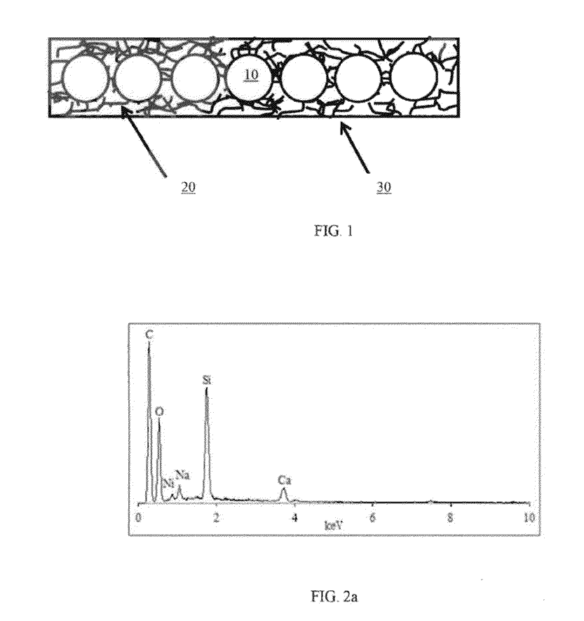

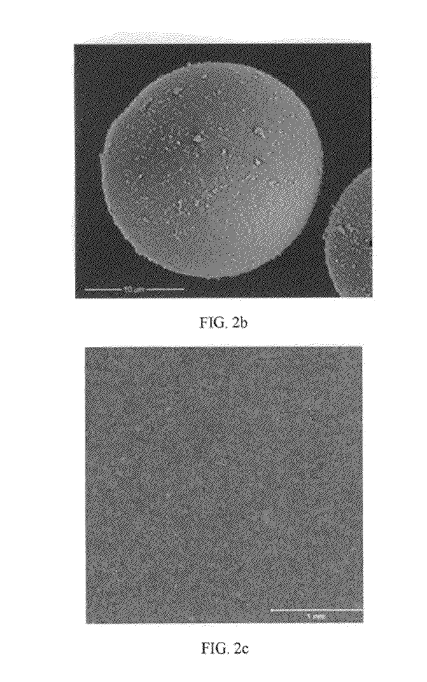

### DRAWINGS

### Reference Numerals

10 Glass microballoons
20 Carbon nanofibers (CNFs)
30 Glass microballoons carbon nanofibers paper (GMB-CNF)

### DETAILED DESCRIPTION OF THE INVENTION

The present invention relates to a free standing paper form of CNFs 10. The present invention further relates to a method of fabricating a freestanding network of CNFs 10. Referring to FIG. 1, the claimed free standing paper form of CNFs 10, also referred to as GMB-CNF 30, is shown. FIG. 1 represents a schematic sectional view of the claimed GMB-CNF 30. The first step of the claimed method involves cleaning and sizing a sufficient number of glass microballoons 10. The number of glass microballoons (GMB) 10 will vary according to the desired and intended size of the free standing network of CNFs 20. The GMBs 10 are of such type that may be commercially produced, are hollow, and may have a diameter ranging from approximately 1 μm to 1000 μm. Next, a catalyst layer is formed on the GMBs 10 to promote the synthesis of CNFs 20. The catalyst layer may comprise the formation of a metal seed layer on said GMBs 10. The metal seed layer may be formed by any suitable means. For example, the electroless deposition of nickel (Ni) may be utilized. However, other metals such as Aluminum, lion, or Cobalt may be used, as well as other forms of creating a catalyst layer may be used.

The next step in the claimed method involves forming a monolayer of the seed-layered GMBs 10 on a suitable substrate. The substrate should be of the type that can withstand high temperatures, such as a silicon wafer. A layer of seed layered GMBs 10 are formed on the substrate by combining the seed-layered GMBs 10 and a solvent to form a suspension and thereafter suspending said suspension in a flow control adaptor. The solvent should be of the type that would promote the cleaning of the seed-layered GMBs 10 and aid in the promotion of a monolayer of GMBs 10. For example, solvents such as ethyl alcohol or isopropyl alcohol may be used. The substrate is then immersed in the suspension. Next, the suspension is removed from the flow control adapter to lower the level of suspension by draining from the bottom. As a result, the seed-layered GMBs 10 are self-assembled and become a layer on the substrate. CNF 20 networks may then be synthesized on the self-assembled seed layered GMBs 10 on the substrate. For example, CNF networks may be synthesized via a dual temperature zone thermal chemical vapor deposition (CVD) method. However, other forms of CNF synthesis may be used. If the CVD method is employed, the process temperatures for such dual temperature zone CVD method should be maintained at suitable ranges, advantageously, from approximately 400° C. to 1000° C., with gas precursors of a suitable type, such as acetylene, argon, hydrogen, and a vapor phase of water. The growth duration of CNFs assuring connections of CNFs to network GMBs, as claimed herein, is, advantageously, from approximately five (5) minutes to thirty (30) minutes. CNFs are formed randomly, but ultimately result in a uniform network on the self assembled seed-layered GMBs. After growth, the resulting freestanding network of CNFs, i.e. the GMB-CNF paper is achieved. Finally, as shown in FIGS. 5a, and 5b, a releasing process involves peeling the GMB-CNF paper off the silicon wafer.

### EXAMPLE

The example set forth below is for illustrative purposes only and are not intended to limit, in any way, the scope of the present invention.

S22 hollow glass microballoons (3M Corporation, USA) were used for GMBs. In this example, the three steps electroless Ni deposition (Ni-ELD) procedure consisting of: functionalization, activation, and deposition, was used for seed layer preparation. The electroless deposition was carried out for 8-10 minutes. The Ni coated GMBs were subjected to analyses of Energy-dispersive X-ray spectra (EDX) and scanning electron microscopy (SEM, FEI Quanta 3D FEG Dual Beam FIB/SEM). A layer of Ni coated microballoons was formed on the surface of 60×18 mm-size Si wafer using a technique similar to dip coating. Approximately 50 mg of Ni coated microballoons were suspended in 30 ml of ethanol and the suspension was added into a flow control adapter (Inner joint size 24/40, Chemiglass) containing the silicon wafer. The wafer was placed vertical in the flow control adapter. The level of the suspension was lowered by draining from the bottom in order to form a layer of microballoons. The drain flow rate was maintained at ˜11.5 ml/min. The CVD system consists of a two stage horizontal tube furnace. The temperature of the first heating zone was maintained at 850° C. For the CNF growth, the wafer was placed in the second heating zone, maintained at 570° C. Argon (Ar) with the flow rate of 160 sccm was run while maintaining the process temperatures. A mixture of 20 sccm C₂H₂, 150 sccm Ar through a flask containing distilled water at room temperature, and 100 sccm H₂ were streamed through for 5, 10, and 20 minutes of growth time. In this process, the catalyst was pretreated by flowing 100 sccm NH₃ for five minutes. The CVD deposition was carried out at atmospheric pressure. The resulting GMB-CNF paper in the present example was subjected to analyses by SEM, transmission electron microscope (TEM, JEOL 100 CX) and Raman Spectroscopy (Renishaw 2000 micro-Raman). The GMB-CNF paper was investigated in J-E characteristics at room temperature. Keithley 6485 picoammeter was used to record the current for testing voltages from 2 to 26 V, with a step of 2 V. The power source was GW Instek GPS-4251, connected in series with the picoammeter.

According to the analyses and tests, the results are described below:

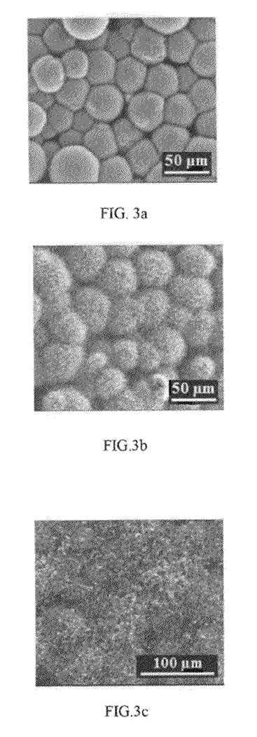

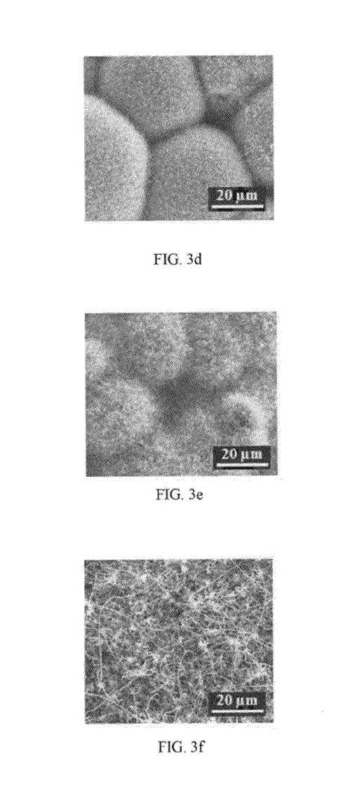

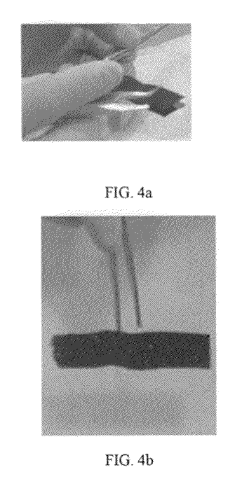

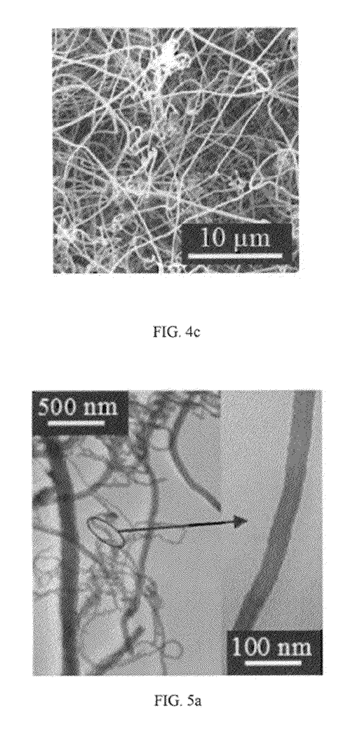

FIG. 3a, FIG. 3b, FIG. 3c shows the SEM images of pieces of the claimed GMB-CNF paper for 5, 10, and 20 minutes of growth. In all depositions, the microballoons were entirely and uniformly covered by nanofibers with a size range of 20-60 nm in diameter. Few bigger diameter fibers are also observed. At 5 and 10 minutes of deposition time, the CNFs were not long enough to form a network. In the case of 5 minutes growth, only closely self-assembled microballoons were held together. The length of the CNFs reaches around 10 μm for this growth time. As the growth time increased to 10 minutes, the nanofibers are long enough to fill the empty spaces among the adjacent microballoons as shown in FIGS. 3b and 3e. At this stage, most of the microballoons on the wafer are interlinked by the fibers. Although the whole system stood as a structure, it was not easily peeled off from the wafer. This effect might be attributed to the stronger interaction between the nanofibers and the wafer than among the nanofibers on the adjacent microballoons. The SEM images for 20 minutes of deposition are shown in FIGS. 3c and 3f. The microballoons in this case are completely covered by random CNF networks with few hundred micron lengths. The paper started self-peeling from the wafer in the regions where there were multiple layers of microballoons due to the interactions among the CNF networks. No other additive is required to completely peel the paper from the wafer. FIG. 4a shows how the paper is peeled from the wafer.

As it can be seen from FIG. 4b, the GMB-CNF paper is free standing even though the monolayer may have some non-uniformity. The reason for the GMB-CNF system to stand as a structure could be that CNFs have generally high van der Waals forces between adjacent nanofibers or nanotubes due to their high aspect ratio. This force of interaction could able to bind the layer of the microballoons. FIG. 4c shows three dimensional CNF random networks that bind the microballoons. The CNFs are seen cross-contacted in random fashion. From SEM analysis, the thickness of the paper was determined to be approximately 75 μm. Also, based on weight measurements of six samples, the bulk density of the paper was found as 0.293 g/cm3, and the average weight fractions of the microballoons and the CNFs as 18.7 and 81.3, respectively.

FIGS. 5a and 5b shows the TEM image and Raman spectra for the CNFs grown on the microballoons. Most of the CNFs are bent and deformed, with few having tubular structure. It has been previously reported that the surface van der Waals forces between cross contacted carbon nanostructures could deform and bend them and significantly modify their idealized geometry, which may be the reason for the deformation of the CNFs. They are also composed of defective graphitic sheets due to the low growth temperature. The Raman spectra of the CNFs show two peaks. The spectrum at around 1332.11 cm−1 is attributed to the D-band which corresponds to the defects of graphitic sheet and the other spectrum at around 1589.05 cm−1 is the G-band, the tangential mode of the graphitic structure. The intensity of D-band is about the same as the intensity of the G-band with intensity ratio, (I_{D}/I_{G}), of 1.001, which also indicates the low crystalinity of the fibers.

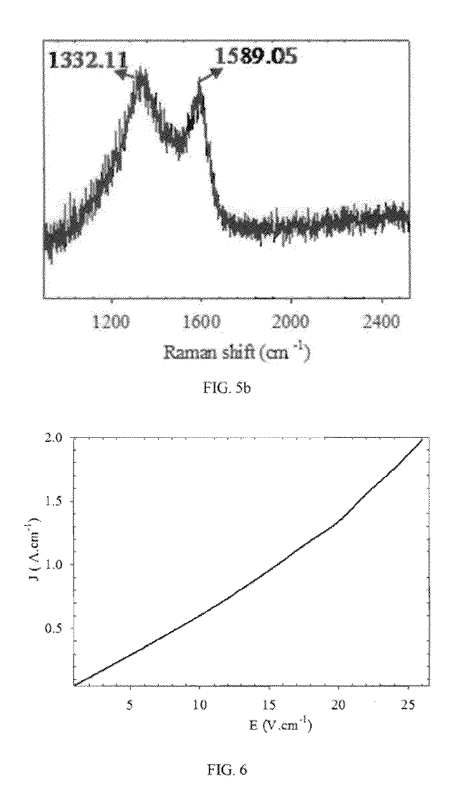

FIG. 6 shows the average J-E characteristics of the GMB-CNF paper samples at room temperature. Samples were cut into 20×5 mm and probed at the two ends, along the length. The distance between probes was maintained at 10 mm. Silver paste (PELCO conductive Silver 187, Ted Pella, Inc.) was coated at the two ends of the specimens to ensure good electrical contacts between the electrodes and the samples. The J-E curve is roughly linear for the voltage ranges, which implies Ohmic contact between the probes and the samples. Electrical conductivity values, measured from the slope of the curve, for the GMB-CNF paper is 7.46 Sm⁻¹.

We claim:

1. A method of fabricating a free standing network of carbon nanofibers comprising:
a. Providing a plurality of glass microballoons,
b. Forming a catalyst layer on said plurality of glass microballoons,
c. Layering said plurality of glass microballoons on a substrate,
d. Synthesizing carbon nanofibers on said plurality of glass microballoons, and
e. Removing the resulting free standing network of carbon nanofibers and glass microballoons from said substrate.

2. The method of claim 1, wherein:
a. Said glass microballoons are hollow and range in size from approximately 1 μm to 1000 μm.
b. Said step of forming a catalyst layer on said plurality of glass microballoons comprises forming a metal seed layer,
c. Said step of layering said plurality of glass microballoons on said substrate further comprises providing a mixture of a solvent and a plurality of seed layered glass microballoons to form a suspension, suspending said suspension in a flow control adapter, immersing said substrate in said suspension, and removing said suspension from said flow control adaptor by draining from the bottom of said flow control adaptor, and
d. Said step of synthesizing carbon nanofibers comprises a dual temperature zone thermal chemical vapor deposition method.

3. The method of claim 2, wherein said the dual temperature zone thermal chemical vapor deposition method is maintained at a temperature from approximately 400° C. to 1000° C. for approximately five to thirty minutes.

4. The method of claim 3, wherein said substrate is a silicon wafer.

5. The method of claim 4, wherein the metal seed layer is formed via the electroless Nickel (Ni) deposition method.

6. The method of claim 5, wherein said solvent is ethyl alcohol.

7. The method of claim 5, wherein said solvent is isopropyl alcohol.

8. A method of fabricating a free standing network of carbon nanofibers comprising:
a. Providing a plurality of glass microballoons that are hollow and range in size from approximately 1 μm to 1000 μm;
b. Forming a metal seed layer on said plurality of glass microballoons via the electroless Nickel (Ni) deposition method,
c. Layering said plurality of seed layered glass microballoons on a silicon wafer by providing a mixture of a solvent and a plurality of seed layered glass microballoons to form a suspension, suspending said suspension in a flow control adaptor, immersing said silicon wafer in said suspension, removing said suspension from said flow control adaptor by draining from the bottom of said flow control adaptor,
d. Synthesizing carbon nanofibers on said plurality of seed layered glass microballoons via a dual temperature zone thermal chemical vapor deposition method maintained at a temperature from approximately 400° C. to 1000° C. for approximately five to thirty minutes, and
e. Removing the resulting free standing network of carbon nanofibers and glass microballoons from said silicon wafer.

9. The method of claim 8, wherein said solvent is ethyl alcohol.

10. The method of claim 8, wherein said solvent is isopropyl alcohol.

11. A freestanding network of carbon nanofibers comprising:
a. A plurality of glass microballoons, and
b. A plurality of carbon nanofibers connected to said plurality of glass microballoons both radially and vertically.

12. The freestanding network of carbon nanofibers of claim 11, wherein said glass microballoons range in size from approximately 1 μm to 1000 μm.
